(19) United States
(12) Patent Application Publication
(10) Pub. No.: US 2013/0192516 A1
(43) Pub. Date: Aug. 1, 2013

(54) METHOD OF PREPARING CAST SILICON BY DIRECTIONAL SOLIDIFICATION

(71) Applicants: Jihong Chen, St. Charles, MO (US); Aditya Deshpande, Chesterfield, MO (US)

(72) Inventors: Jihong Chen, St. Charles, MO (US); Aditya Deshpande, Chesterfield, MO (US)

(73) Assignee: MEMC SINGAPORE PTE. LTD. (UEN200614794D), Singapore (SG)

(21) Appl. No.: 13/360,116

(22) Filed: Jan. 27, 2012

(51) Int. Cl. C30B 19/08

(52) U.S. Cl. 117/54

(57) ABSTRACT

A method of preparing a silicon melt in a crucible for use in the manufacture of cast silicon, wherein the crucible comprises an opening, an opposing bottom surface, and at least one sidewall joining the opening and the bottom surface. The method comprises charging a silicon spacer to the bottom surface of the crucible; arranging a monocrystalline silicon seed crystal on the silicon spacer such that no surface of the monocrystalline silicon material is in contact with the bottom surface of the crucible; charging polycrystalline silicon feedstock to the crucible; and applying heat through at least one of the opening and the at least one sidewall in order to form a partially melted charge of silicon in the crucible.

### FIELD OF THE INVENTION

The field of the invention relates generally to a method for preparing crystalline silicon ingots by a directional solidification process, and more particularly, the present invention relates to a method for preparing cast silicon ingots having reduced impurities and non-random crystal orientation.

### BACKGROUND OF THE INVENTION

A crystalline silicon ingot, e.g., for use in manufacture of photovoltaic cells, may be produced by a casting process. In such processes, molten silicon is contained in a crucible and is cooled in a controlled manner to permit the crystallization of the silicon contained therein. In general, the cooling is controlled in order to achieve directional solidification (DS) in which silicon is solidified starting from the bottom of the crucible such that a solid-liquid interface generally progresses in a direction perpendicular from the bottom toward the top of the crucible. In general, a cast crystalline silicon ingot produced in such a manner may be an agglomeration of crystal grains (i.e., multicrystalline) with the orientation of the grains being random relative to each other due to the high density of heterogeneous nucleation sites at the crucible wall. Once the crystalline ingot is formed, the ingot may be cut into blocks and further cut into wafers. Multicrystalline silicon is generally preferred silicon source for photovoltaic cells rather than single crystal silicon produced by the Czochralski process, for example, due to its lower cost resulting from higher throughput rates, less labor-intensive operations, and the reduced cost of supplies as compared to typical single crystal silicon production.

### BRIEF DESCRIPTION OF THE INVENTION

Briefly, therefore, the present invention is directed to a method of preparing a silicon melt in a crucible for use in the manufacture of cast silicon, wherein the crucible comprises an opening, an opposing bottom surface, and at least one sidewall joining the opening and the bottom surface. The method comprises charging a silicon spacer to the bottom surface of the crucible; arranging a monocrystalline silicon seed crystal on the silicon spacer such that no surface of the monocrystalline silicon material is in contact with the bottom surface of the crucible; charging polycrystalline silicon feedstock to the crucible; and applying heat through at least one of the opening and the at least one sidewall in order to form a partially melted charge of silicon in the crucible.

The present invention is further directed to a method of manufacturing cast silicon. The method comprises charging a silicon spacer to a crucible, wherein the crucible comprises an opening, an opposing bottom surface, and at least one sidewall joining the opening and the bottom surface; arranging a monocrystalline silicon seed crystal on the silicon spacer such that no surface of the monocrystalline silicon seed crystal is in contact with the bottom surface of the crucible; charging polycrystalline silicon feedstock to the crucible; applying heat through at least one of the opening and the sidewall in order to form a partially melted charge of silicon in the crucible, wherein the heat is applied to melt the polycrystalline silicon feedstock such that a liquid-solid interface progresses in a direction generally perpendicular from the opening of the crucible and toward the bottom surface of the crucible and the liquid-solid interface is maintained flat when progresses toward the surface of seed crystals; and reducing the heat applied to the opening of the crucible and/or cooling the bottom of the crucible after the liquid-solid interface contacts the monocrystalline silicon seed crystal, thereby causing the liquid-solid interface to reverse direction and progress in a direction generally perpendicular from the bottom surface of the crucible and toward the opening of the crucible, wherein at least a portion of the monocrystalline silicon seed crystal remains solid throughout the entire method.

### BRIEF DESCRIPTION OF THE DRAWINGS

FIG. 1 is a perspective view of a crucible body.

FIG. 2A is a top-view depiction of a lattice of polycrystalline silicon strips supporting a layer of monocrystalline silicon seed crystals.

FIG. 2B is a side-view depiction of a lattice of polycrystalline silicon strips supporting a layer of monocrystalline silicon seed crystals.

FIG. 3 is a depiction of the heating apparatus for preparing a silicon melt.

FIG. 4 is a depiction of a bottom surface of a crucible to which granular polycrystalline silicon has been charged.

FIG. 5 is a depiction of an arrangement of monocrystalline silicon seed crystals on polycrystalline silicon strips.

FIG. 6 is a depiction of an arrangement of a multilayer of monocrystalline silicon seed crystals and sacrificial seed crystals on polycrystalline silicon strips.

### DETAILED DESCRIPTION OF THE EMBODIMENT(S) OF THE INVENTION

The present invention is directed to a method for preparing a semiconductor ingot and, more particularly, to preparing a semiconductor ingot by a casting method. The cast semiconductor ingot is prepared by a directional solidification method in which molten semiconductor material, e.g. silicon, is cooled in a crucible such that the solid-liquid interface progresses in a direction generally perpendicular from the bottom of the crucible toward the top. Methods for crystallizing silicon are generally described by K. Fujiwara et al. in Directional Growth Medium to Obtain High Quality Polycrystalline Silicon from its Melt, Journal of Crystal Growth 292, p. 282-285 (2006), which is incorporated herein by reference for all relevant and consistent purposes.

In general, the semiconductor material for preparing a cast semiconductor ingot according to the present invention may comprise materials suitable for use as photovoltaics. Suitable materials that may be grown by the cast method according to the present invention include silicon, gallium arsenide (GaAs), calcium arsenide (CaAs), cadmium telluride (CdTe), and copper indium diselenide (CuInSe₂). The ingot can be prepared with intentional impurities, e.g., boron, arsenic, phosphorus, and gallium, to obtain certain electrical properties.

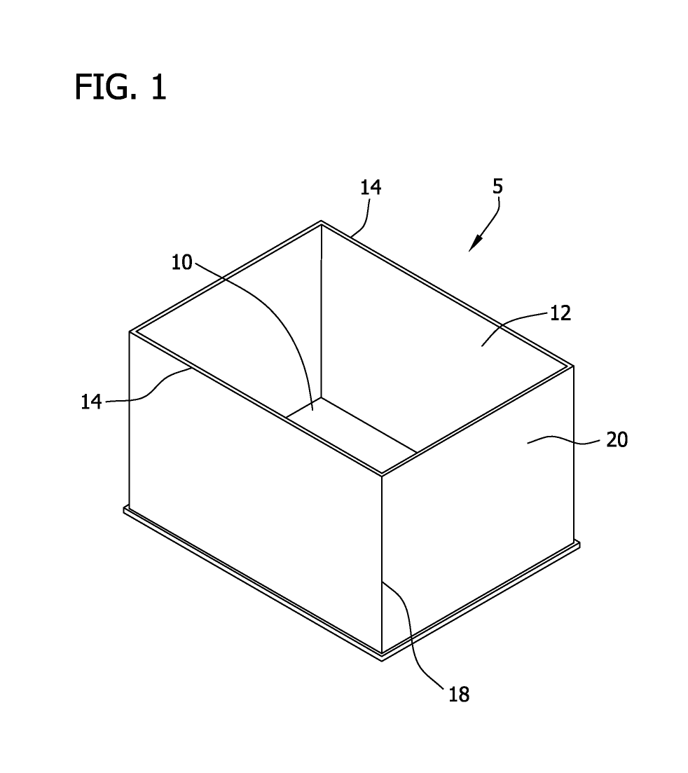

According to some embodiments of the method of the present invention, a crystalline silicon ingot is produced by directional solidification. Cast silicon may be grown in a crucible such as the crucible depicted in FIG. 1 generally by charging the crucible with polycrystalline feedstock, melting the feedstock, and then solidifying the molten silicon unidirectionally from the bottom of the crucible toward the top of the crucible. Conventional methods yield cast silicon ingot having randomized crystal grain orientations due to sporadic nucleation of crystals by nucleation of particles in the melt or on the sidewall of the crucible. The method of the present invention substantially inhibits sporadic nucleation of randomly oriented crystals in the solidifying melt and advantageously yields a crystalline silicon ingot having reduced impurity content and non-random crystal orientation. The non-random crystal orientation is achieved by seeding the crucible in which the crystalline silicon ingot is prepared with a monocrystalline seed crystal or multiple monocrystalline seed crystals. When multiple monocrystalline seed crystals are used, preferably each seed crystal has identical crystal orientation and the same lateral dimension of the final wafer. In this manner, a crystalline silicon ingot is prepared that is “mono-like” in that the ingot is prepared from multiple monocrystalline silicon seed crystals, but each crystal has identical crystal orientation and the same lateral dimension of the wafer such that the crystal orientation of the crystalline silicon ingot is substantially identical throughout the bulk region of the ingot. In some embodiments, each wafer is made of almost one large grain.

According to the method of the present invention, silicon may be loaded into a crucible to form a silicon charge. Referring now to FIG. 1, a crucible body 5 for use in embodiments of the present invention is exemplified. The crucible body 5 depicted in FIG. 1 has a bottom 10 and at least one sidewall 14 that extends perpendicularly from the base or bottom 10. While the crucible body 5 is illustrated with four flat sidewalls 14 being shown, it should be understood that a crucible for use in the method of the present invention may include fewer than four sidewalls or may include more than four sidewalls without departing from the scope of the present disclosure. Also, a corner 18 joining two sidewalls 14 may be at any angle suitable for forming the enclosure of the crucible body and may be sharp as illustrated in FIG. 1 or may be rounded. Additionally, the at least one sidewall 14 may not necessarily be flat as depicted in FIG. 1. In some embodiments, a crucible may contain at least one curved sidewall. In some embodiment, a crucible contains one curved sidewall, e.g., the crucible may be frusto-conical or cylindrical. In some embodiments, the crucible body 5 has at least one sidewall that is generally cylindrical in shape. The at least one sidewall 14 of the crucible body 5 has an inner surface 12 and an outer surface 20. The crucible body 5 depicted in FIG. 1 is generally open, i.e., the body 5 may not include a top. It should be noted, however, the crucible body 5 may have a top or lid (not shown) opposite the bottom 10 without departing from the scope of the present invention.

In some embodiments of the present invention, a crucible, such as the crucible body 5 depicted in FIG. 1, has four sidewalls 14 of substantially equal length (e.g., the crucible has a generally square base 10 and the crucible body 5 is cubical). The length of the sidewalls 14 may be at least about 25 cm, at least about 50 cm, at least about 60 cm, at least about 70 cm, at least about 80 cm, or even at least about 130 cm, such as between about 50 cm and about 140 cm. In preferred embodiments, the crucible body is cubical. An exemplary crucible may have exterior dimensions of 870 mm×870 mm and interior dimensions of 840 mm×840 mm. The height of the sidewalls 14 may be at least about 15 cm, at least about 25 cm or even at least about 35 cm, such as about 40 cm in height or about 60 cm in height, such as between about 25 cm and about 70 cm. In this regard, the volume of the crucible (in embodiments wherein a square or rectangular base is used or wherein the crucible is cylindrical or round or in embodiments wherein another shape is used) may be at least about 0.05 m³, at least about 0.15 m³ or at least about 0.25 m³, such as about 0.28 m³. Further in this regard, it should be understood that crucible shapes and dimensions other than as described above may be used without departing from the scope of the present disclosure. In one or more particular embodiments of the present disclosure, the crucible body 5 has four sidewalls 14 that are each about 87.7 cm in length and 40 cm in height and the crucible has a volume of about 0.31 m³. In one or more particular embodiments of the present disclosure, the crucible body 5 has four sidewalls 14 that are each about 133 cm in length and 60 cm in height.

The crucible for use in the method of the present invention, such as the crucible body 5 depicted in FIG. 1, may be constructed of any material suitable for the solidification of semiconductor material. For example, the crucible may be constructed from a material selected from silica, silicon nitride, silicon carbide, graphite, mixtures thereof and composites thereof. Composites may include, for example, a base material with a coating thereon. Composite materials include, for example, silica coated with silicon nitride and graphite coated with calcium chloride and/or silicon nitride. In some embodiments, the crucible interior surface may be coated with a silicon nitride coating as described in U.S. Pub. No. 2011/0015329 (assigned to MEMC Singapore PTE. LTD.), which is incorporated herein by reference for all relevant and consistent purposes. It should be noted that some crucible body materials may not inherently be a source of oxygen contamination (e.g., graphite), however they may have other attributes to be taken into consideration when designing a system (e.g., cost, contamination and the like). In addition, the material preferably is capable of withstanding temperatures at which such semiconductor material is melted and solidified. For example, the crucible material is suitable for melting and solidifying semiconductor material at temperatures of at least about 300° C., at least about 1000° C. or even at least about 1580° C. for durations of at least about 10 hours or even as much as 100 hours or more.

Again referring to FIG. 1, the thickness of the bottom 10 and at least one sidewall 14 may vary depending upon a number of variables including, for example, the strength of material at processing temperatures, the method of crucible construction, the semiconductor material of choice and the furnace and process design. Generally, the thickness of the crucible may be from about 5 mm to about 50 mm, from about 10 mm to about 40 mm or from about 15 mm to about 25 mm.

According to the method of the present invention, silicon is charged to a crucible according to a sequence of steps prior to preparing the silicon melt and unidirectional solidification. The sequence of silicon charging provides a method that substantially inhibits sporadic nucleation of randomly oriented crystals and yields a cast silicon ingot having substantially reduced impurity content. Control of the crystal orientation in the cast silicon ingot provides several notable advantages. For example, crystal orientation affects surface texturing characteristics, which significantly impacts solar cell conversion efficiency; crystal orientation affects dislocation generation and propagation; randomly nucleated crystals tend to have much higher dislocation density; and randomly nucleated crystals generally need additional post casting processing, such as isotropic etching in acid. In some embodiments of the present invention, a monocrystalline silicon seed crystal or multiple monocrystalline silicon seed crystals are arranged near the bottom of the crucible prior to loading the bulk of the polycrystalline feedstock. The monocrystalline silicon seed crystals are arranged in such a manner that none of the surfaces of the seed crystals are in contact with the bottom surface of the crucible. In preferred embodiments of the invention, the monocrystalline silicon seed crystals are arranged in such a manner that none of the surfaces of the seed crystals are in contact with the bottom surface of the crucible and none of the surfaces of the seed crystals are in contact with the at least one sidewall of the crucible. In embodiments wherein a crucible is used with multiple sidewalls, preferably, the seed crystals are arranged such that none of the surfaces thereof are in contact with any crucible sidewall surface. In preferred embodiments wherein, e.g., the crucible comprises four sidewalls and is cube or cuboidal in shape, the monocrystalline silicon seed crystals are arranged in such a manner that none of the surfaces of the seed crystals are in contact with the bottom surface of the crucible and none of the surfaces of the seed crystals are in contact with any of the four sidewalls of the crucible.

Arranging the monocrystalline silicon seed crystals such that none of the surfaces of the seed crystals are in contact with the bottom of the crucible, and preferably none of the surfaces are in contact with the at least one sidewall surface, is accomplished by first charging a silicon spacer material to the bottom surface of the crucible. The silicon spacer material may be polycrystalline silicon, amorphous silicon, multicrystalline silicon prepared by directional solidification, or monocrystalline silicon prepared by the Czochralski method. Preferably, the silicon spacers comprise high purity silicon. Polycrystalline silicon refers to crystalline silicon with micron order grain size and multiple grain orientations located within a given body of silicon. For example, the grains are typically an average of about submicron to submillimeter in size (e.g., individual grains may not be visible to the naked eye), and grain orientation distributed randomly throughout. The silicon spacer materials may be selected from among granular polycrystalline silicon, chunks or chips of polycrystalline, large grain multicrystalline or monocrystalline silicon, or silicon that has been cut into uniform shapes, such as, for example, strips, tiles, or blocks.

Granular polycrystalline silicon is in the form of a plurality of free flowing silicon particles (granules). Processes for preparing granular polycrystalline silicon are described in, for example, U.S. 2008/0187481 and U.S. Pat. Nos. 5,405,658; 5,322,670; 4,868,013; 4,851,297; and 4,820,587. An exemplary granular silicon particle may have a seed produced in fragmentation process, which is surrounded by high purity silicon. The seed can suitably be formed by striking a target piece of silicon with a projectile piece of silicon, substantially as set forth in U.S. Pat. No. 4,691,866. The silicon surrounding the seed particle is high purity silicon that has been deposited on the seed particle by decomposition of a silicon-bearing compound as the seed is contacted by a silicon deposition gas (e.g., silane) in a pair of fluidized bed CVD reactors. Granular polycrystalline silicon is generally spherical having widely varying particle sizes. The granules may have diameters generally varying from about 0.25 mm to about 4 mm, preferably between about 1 mm and about 3 mm. Preferably, sufficient granular polycrystalline silicon is charged to the crucible body to enable arrangement of monocrystalline seed crystals thereon such that no surfaces of the seed crystals are in contact with the bottom surface of the crucible. Amounts of granular silicon sufficient to ensure such arrangement will depend upon the crucible body dimensions and thus may be determined empirically. Sufficient granular polycrystalline silicon may be charged to the bottom surface of the crucible to cover at least about 2% of the total surface area of the bottom surface of the crucible, preferably at least about 5% of the total surface area, or even at least about 10% of the total surface area.

In an exemplary embodiment, a crucible having a cuboid or cubical shape having interior bottom surface dimensions of 84 cm by 84 cm may be charged with about 5 kg of granular polycrystalline silicon, wherein at least about 90% of the particles have a diameter between 1 mm and 3 mm. This mass of granular polycrystalline silicon generally covers about 5% of the bottom surface of the crucible having the specified dimensions, which is sufficient to support the monocrystalline silicon seed crystals that are arranged on top of the granular spacers in the next step such that no surface of the crystals contacts the bottom surface of the crucible and preferably no surface contacts any sidewall surface.

The varying diameters of granular polycrystalline silicon could make it potentially difficult to control the crystal orientation of the monocrystalline silicon seed crystals arranged thereon. In view thereof, preferred embodiments of the invention employ chunk polycrystalline silicon spacer or polycrystalline silicon spacer in the form of more uniform shapes such as tiles, blocks, or strips.

In some embodiments, the polycrystalline silicon spacer comprises chips or chunks of polycrystalline silicon. Chunk polycrystalline silicon may be prepared by the Siemens process. The preparation of chunk polycrystalline silicon is described in F. Shimura, Semiconductor Silicon Crystal Technology, pages 116-121, Academic Press (San Diego Calif., 1989) and the references cited therein. In general, the average particle size of chunk polycrystalline silicon is at least about 3 mm and generally ranges from about 3 mm to about 200 mm. Preferably at least 50% and even more preferably at least 85% of the chunk silicon ranges in size from about 1 mm to about 5 mm, such as about 3 mm to about 5 mm. Preferably, the sizes of the chunk polycrystalline silicon are relatively uniform to allow for arrangement of seed crystals on the chunk polycrystalline silicon spacer such that the seed crystals are arranged in identical crystal orientation.

In some embodiments, silicon spacer comprises silicon having uniform shapes and sizes. The silicon spacer materials having uniform shapes and sizes are advantageous since use of such a silicon spacer enables careful arrangement of the monocrystalline silicon seed crystals according to crystal orientation within the crucible. Such uniform shapes include tiles, strips, and blocks of silicon. In a preferred embodiment, the silicon spacer comprises strips of silicon having a thickness of between about 250 micrometers and 1250 micrometers, such as about 750 micrometers. Due to some non-uniformity of the silicon strips, which may result from warp and bow of the source material, the thickness of the silicon strip may be measured from a point of contact between the spacer material and the bottom surface and a point of contact between the spacer and the monocrystalline silicon seed crystal. Such strips may have lengths between about 20 millimeters and about 450 millimeters, or between 50 millimeters and about 450 millimeters, such as between about 50 mm and about 300 mm, preferably between about 200 millimeters micrometers and about 300 millimeters.

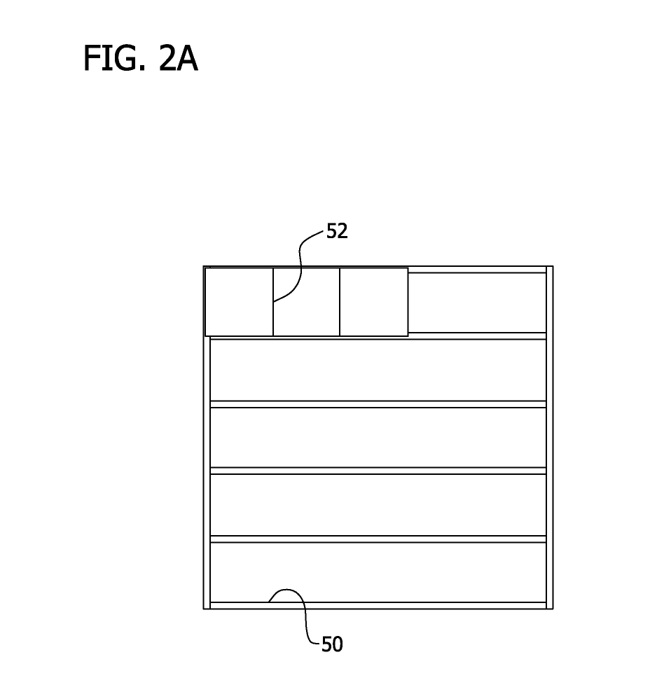

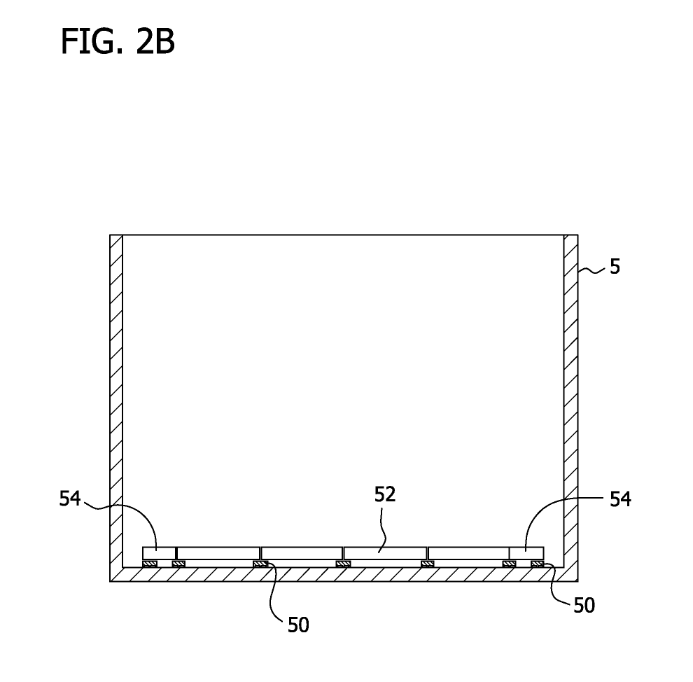

In an exemplary embodiment, a crucible having a cuboid or cubical shape having bottom interior surface dimensions of 84 cm by 84 cm may be lined with about 28 silicon strip spacers having a thickness of about 0.75 mm and a length of about 200 mm. See, for example, FIGS. 2A (top view) and 2B (side view) which depict an arrangement of polycrystalline silicon strips 50 arranged in a manner sufficient to support tile-shaped monocrystalline silicon seed crystals 54 on the bottom surface of a crucible 5. The side view depicted in FIG. 2B additionally shows sacrificial monocrystalline seed crystals 54 around the periphery of the tile-shaped monocrystalline silicon seed crystals 52. This depiction is not meant to be limiting as other spacer shapes and arrangements other possible while still falling within the scope of the present invention. In general, strips, tiles, or blocks of silicon may be arranged to provide a lattice of silicon spacers that supports the monocrystalline silicon seed crystals that are arranged thereon in the next step.

According to the next step of the process of the present invention, at least one monocrystalline silicon seed crystal is arranged on top of the silicon spacer such that no surface of the seed crystal contacts the bottom surface of the crucible and preferably no surface of the seed crystal contacts any surface of the at least one sidewall. In preferred embodiments wherein the crucible is, e.g., cubicle, no surface of the monocrystalline seed crystal(s) is in contact with the bottom surface of the crucible or the surfaces of any of the four sidewalls. In some preferred embodiments, multiple monocrystalline silicon seed crystals are arranged on top of silicon spacer such that no surface of any of the seed crystals contacts the bottom surface of the crucible and preferably no surface of any of the seed crystal contacts the surface of the at least one sidewall. Monocrystalline silicon refers to a body of single crystal silicon, having one consistent crystal orientation throughout. The monocrystalline silicon seed crystals for use in the method of the present invention may be produced by conventional methods for producing monocrystalline silicon ingots such as the Czochralski method or float zone method. In both processes, a cylindrically shaped ingot of monocrystalline silicon is produced. For a CZ process, an ingot is slowly pulled out of a pool of molten silicon. For a FZ process, solid material is fed through a melting zone and re-solidified on the other side of the melting zone. The ingot may be segmented into a plurality of segments, and each segment sliced into a plurality of wafers, which may be polished and etched according to methods known in the art. Each wafer is finished by, e.g., grinding and polishing, so that its two opposite faces are flat, such that the wafer comprises two major, generally parallel surfaces, one of which is a front surface and the other of which is a back surface. The surfaces may be etched by, e.g., chemical etching steps, so that dust, residual particles, and zones damaged during the preceding material-removal steps are eliminated. Etching the seed crystals prior to use in the cast ingot growth method decreases the dislocation density in the final ingot product.

In general, the monocrystalline silicon seed crystal(s) comprise highly pure, low defect silicon. In preferred embodiments, the dislocation density is no greater than about 5×10⁴ dislocations/cm², preferably no greater than about 1×10⁴ dislocations/cm², more preferably no greater than about 5×10³ dislocations/cm², even more preferably less than 1×10³ dislocations/cm². In some embodiments, the dislocation density of the monocrystalline silicon seed crystals may be no greater than about 100 dislocations/cm². These dislocations may be revealed on the surface in the form of etch pits. Low dislocation density ingots may be obtained by minimizing the dislocations densities of the monocrystalline silicon seed crystal(s).

In general, the monocrystalline silicon seed crystals may have a nitrogen concentration ranging from 1×10¹² nitrogen atoms/cm³ to about 5×10¹⁵ nitrogen atoms/cm³. In general, the monocrystalline silicon seed crystals may have an oxygen concentration less than about 1×10¹⁸ oxygen atoms/cm³, preferably less than about 5×10¹⁷ oxygen atoms/cm³. In general, the monocrystalline silicon seed crystals may have a carbon concentration less than about 5×10¹⁷ carbon atoms/cm³, preferably less than about 5×10¹⁶ carbon atoms/cm³. In general, the monocrystalline silicon seed crystals may have an iron concentration less than about 5×10¹³ carbon atoms/cm³, preferably less than about 1×10¹² carbon atoms/cm³. Low dislocation density ingots may be obtained by minimizing the impurity contents, particularly nitrogen and carbon, in the monocrystalline silicon seed crystal(s). Impurities, such as Si₃N₄ and SiC may be sources of dislocations in the final ingot product.

The monocrystalline silicon seed crystal or seed crystals used for casting processes may be of any desired size and shape, but are suitably geometrically shaped pieces of monocrystalline silicon, such as, for example, circular, triangular, square, rectangular, hexagonal, rhomboid or octagonal shaped pieces of silicon. The monocrystalline silicon is preferably cut into shapes conducive to tiling, so they can be placed or “tiled” edge-to-edge and conformed to the bottom of a crucible in a desired pattern. For example, when the interior bottom surface of the crucible is rectangular or square, the monocrystalline seed crystals are generally further sliced into rectangular or square tiles, the rectangular or square tiles comprising two major, generally parallel surfaces, one of which is a front surface and the other of which is a back surface. The dimensions, e.g., lengths of a rectangular or square seed crystal tile or diameter of a circular seed crystal wafer, generally range from about 50 mm to about 450 mm, such as between about 100 mm and about 200 mm. In some embodiments, the lengths of the tiles may be larger, such as at least 700 mm or even as greater than 1100 mm. The tiles may have a thickness ranging from 5 mm to 100 mm, such as between about 10 mm and about 50 mm.

In some embodiments, the tile dimensions may be 156 mm×156 mm. For example, 16 monocrystalline seed crystals may be arranged 4×4, each of the seed crystals having a length of about 156 mm to form a 624 mm by 624 mm matrix of seed crystals. The thickness of the monocrystalline seed crystals ranges from about 1 cm to about 5 cm, wherein the thickness is measured from the lowest point on the front surface to a transverse point on the back surface. Square-shaped tiles are particularly advantageous since most solar wafer has a square shape, it is easy to align the edge of the seeds, it is easy to generate and recycle, and square tiles enable geometric arrangement of monocrystalline silicon seed crystals on top of the polycrystalline silicon spacer strips. Such arrangements include a single monocrystalline silicon seed crystal that encompasses nearly the entire area of the bottom surface of the crucible and arrangements that employ multiple monocrystalline silicon seed crystals such as two seed crystals (arranged 1×2), three seed crystals (arranged 1×3), four seed crystals (arranged 1×4 or 2×2), five seed crystals (arranged 1×5), six seed crystals (arranged 1×6 or 2×3), seven seed crystals (arranged 1×7), eight seed crystals (arranged, for example, 2×4), nine seed crystals (arranged, for example, 3×3), ten seed crystals (arranged, for example, 2×5) and larger numbers, such as 16 seed crystals (arranged, for example, 4×4 or 2×8), 25 seed crystals (arranged, for example, 5×5), 36 seed crystals (arranged, for example, 6×6), and so on.

According to the process of the present invention, each monocrystalline silicon seed crystal may be arranged in the crucible in identical crystal orientation, e.g., (100), (110), and (111), with preferred orientations being (110) or (110). In some embodiments, a single large monocrystalline silicon seed crystal is arranged that encompasses nearly the entire area of the bottom surface of the crucible, said single seed crystal having crystal orientation of (100), (110), or (111), with preferred orientations being (110) or (100). In some embodiments, multiple monocrystalline silicon seed crystals of identical crystal orientation are tiled (e.g., 1×2, 1×3, 1×4, 2×2, 1×5, 2×3, 1×6, 1×7, 2×4, 3×3, 2×5, 4×4, 5×5, 6×6, and so on) near the bottom surface of the crucible in a predetermined geometric orientation or pattern across, for example, the bottom and one or more of the sides and the bottom surfaces of a crucible. In embodiments wherein multiple monocrystalline silicon seed crystals are tiled, preferably every crystal is arranged having identical crystal orientation, e.g., all crystals are (100), all crystals are (110), or all crystals are (111), with preferred orientations being (110) or (100). For example, 16 monocrystalline seed crystals may be arranged 4×4, each of the seed crystals having a length of about 156 mm to form a 624 mm by 624 mm matrix of seed crystals and all crystals have (100) orientation. In an alternative exemplary embodiment, 16 monocrystalline seed crystals may be arranged 4×4, each of the seed crystals having a length of about 156 mm to form a 624 mm by 624 mm matrix of seed crystals and all crystals have (110) orientation. In yet another exemplary embodiment, 16 monocrystalline seed crystals may be arranged 4×4, each of the seed crystals having a length of about 156 mm to form a 624 mm by 624 mm matrix of seed crystals and all crystals have (111) orientation. Other preferred embodiments comprise arrangements of 1 large crystal having crystal orientation of (100), (110), or (111), 2 crystals arranged in a 1×2 orientation, in which both have identical crystal orientation, or 9 crystals arranged in a 3×3 matrix, in which all have identical crystal orientation. It is preferable that the seed or seeds are arranged to cover a substantial portion of the entire crucible surface preferably without any crystal surface touching the crucible sidewall surfaces, so that when the seeded crystal growth solidification front (i.e., the solid-liquid interface) progresses perpendicularly from the bottom of the crucible toward the top (i.e., lid) or opening of the crucible during the cooling phase of the process, nearly the entire crucible cross-section may be utilized to prepare a multi-crystalline cast silicon ingot. In general, surface coverage is at least 60% of the surface area, preferably at least 70% coverage of the surface area, and even more preferably at least 90% coverage of the surface area.

In some embodiments of the invention, relatively narrow cuboidal shaped mono crystals of same orientation are placed at the peripheral of the seed tiles to prevent mono growth from contacting the multi growth in the edge region. The mono crystals grown from the narrow seeds are not intended to be used in the final product and will be recycled. They are referred to herein as “sacrificial crystals.” The sacrificial seeds and crystals grown on them prevent the misoriented grain from growing into the internal mono like crystals.

In some embodiments, monocrystalline silicon seed crystals are arranged such that no surface of any seed crystal is in contact with either of the bottom of the crucible or any sidewall of the crucible and sacrificial seed crystals are arranged around the periphery of monocrystalline silicon seed crystals in order to form a buffer of sacrificial seeds surrounding the monocrystalline silicon seed crystals. For example, multiple square-shaped and rectangular-shaped tiles of monocrystalline seed crystals may be arranged (e.g., 1×2, 1×3, 1×4, 2×2, 1×5, 2×3, 1×6, 1×7, 2×4, 3×3, 2×5, 4×4, 5×5, 6×6, and so on) in the center of the crucible and strips (e.g., thin rectangular strips) of sacrificial seeds are arranged between the layer of monocrystalline seed crystals and the crucible side wall. Referring again to FIG. 2B, which is a cross-sectional side view of monocrystalline silicon seed crystals 52 having sacrificial silicon seed crystals 54 arranged around the periphery of the monocrystalline silicon seed crystals 52. None of the surfaces of the monocrystalline silicon seed crystals 52 and the sacrificial silicon seed crystals 54 contact the bottom surface of the crucible or the sidewalls.

After the monocrystalline silicon seed crystal or multiple monocrystalline silicon seed crystals are arranged in the crucible such that no surfaces of the monocrystalline silicon seed crystal or multiple crystals are in contact with the bottom surface of the crucible and preferably no surfaces of the monocrystalline silicon seed crystal or multiple crystals are in contact with the at least one sidewall of the crucible, the bulk of the polycrystalline silicon feedstock is charged to the crucible. The polycrystalline silicon feedstock charged to the crucible is a mass sufficient to prepare a cast mono like crystalline silicon ingot of the desired size and mass. In some embodiments, a cast silicon ingot may have a mass between about 270 kg and about 2000 kg, preferably between about 450 kg and about 1650 kg. In general, the silicon placer and the monocrystalline seed crystals comprise between about 10% and about 15% of the total mass of the cast silicon ingot, preferably between about 6% and about 10% of the total mass of the cast silicon ingot. In view thereof, the mass of polycrystalline silicon feed stock charged to the crucible generally ranges between about 270 kg and about 2000 kg, preferably between about 450 kg and about 1650 kg. The polycrystalline silicon feedstock may comprise granular polycrystalline, chunk polycrystalline, or a combination of the granular and chunk polycrystalline silicon.

In some embodiments, after the spacers and monocrystalline seeds are arranged and sacrificial seeds, if used, in general, a gap of about 2 to 5 centimeters may be left after the seeds are arranged to allow for the seeds and sacrificial crystals to expand during the temperature ramp-up. Granular polycrystalline silicon may then be charged to the crucible in order to fill in the gap between the seed crystals and the crucible wall. Silicon in the shape of chunks, slabs, or chips may then be charged to the seed arrangement, which will generally leave a gap of about 2 to 5 centimeters between the polycrystalline silicon and the crucible wall. Again, granular polycrystalline silicon may be charged to the crucible to fill the gap between the chunk polysilicon and the crucible wall. This same stacking procedure may be employed until crucible is full. The amount of seeds, chunk Si and granular Si and dopant are precisely calculated and weighed before charge the crucible.

Once the polycrystalline feedstock is loaded into the crucible and on top of the monocrystalline silicon seed crystal(s), the silicon charge may be heated to a temperature above about the melting temperature of the charge to form a silicon melt, wherein the silicon melts first at the opening of the crucible and the solid-liquid interface progresses in a directional perpendicular from the opening of the crucible and toward the bottom of the crucible. Silicon has a melting point around 1414° C. Accordingly, the silicon charge may be heated to at least about 1414° C. to form the silicon melt and, in another embodiment, at least about 1450° C. to form the silicon melt, or even at least about 1500° C. In some preferred embodiments, the charge is heated to a temperature of about 1495° C. The heating elements, such as graphite resistance heaters, may be arranged near the opening of the crucible and around the sidewalls of the crucible. A heat exchanger and optionally a water cooling jacket may be arranged near or congruent with the bottom of the crucible in order to maintain at least a portion of the monocrystalline silicon seed crystals in a solid state. The heat exchanger and optionally water cooling jacket maintain the temperature of the bottom of the crucible below the melting point of silicon by radiation, conduction, or a combination of the two such that at least a portion of the monocrystalline silicon seed crystals remain in a solid state during the melting phase of the process. In general, the temperature of the crucible bottom adjacent the seed crystals is held below about 1410° C., below about 1400° C., and preferably below about 1350° C., such as about 1310° C.

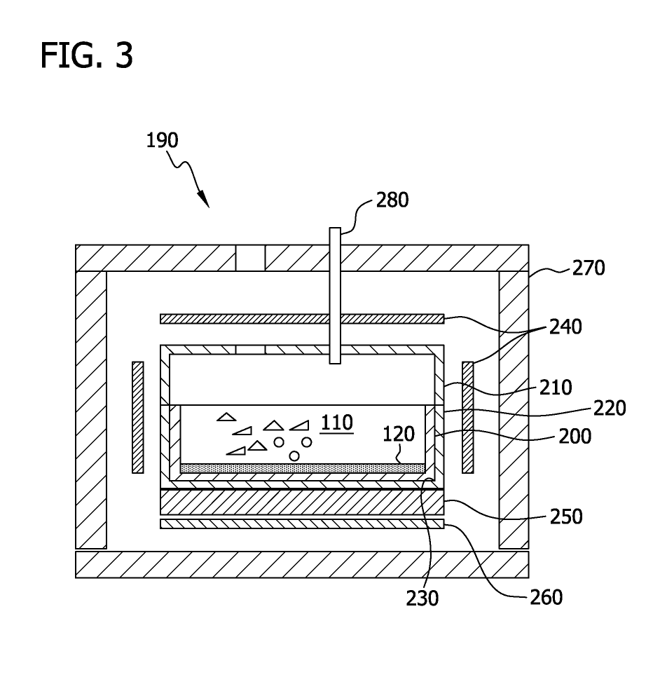

With reference now to FIG. 3, a heating apparatus 190 that may be used in accordance with the method of the present invention is depicted. In the heating apparatus 190 depicted in FIG. 3, heating elements 240 are located at the top or lid 210 of the crucible and the side 220 of the crucible 200. The use of the lid 210 is an optional feature of this heating apparatus 190. In some embodiments, the crucible may be heated without a lid. In some embodiments, the heating elements 240 are located only at the top of the crucible. In some embodiments, the heating elements 240 are located only at the sidewall(s) of the crucible. A heat exchange block 250 is located near the bottom 230 of the crucible 200. In some embodiments, the heat exchange block 250 is congruent with the bottom 230 of the crucible 200. The arrangement of the heating elements 240 and the heat exchange block 250 enable a thermal profile in the crucible 200 in which the silicon feedstock 110 melts substantially unidirectionally in the direction perpendicular from the top or lid 210 of the crucible 200 toward the bottom 230 of the crucible 200, upon which are arranged monocrystalline silicon seeds 120. Stated another way, the heating elements 240 are arranged such that the solid-liquid interface progresses away from the top or lid 210 (or the opening in embodiments wherein the crucible does not have a lid) of the crucible 200 toward the bottom 230 of the crucible 200. The bottom 230 of the crucible 200 may be actively or passively cooled to maintain the monocrystalline silicon seeds 120 in a solid state. For example, a heat exchange block 250, such as a graphite block, may be placed in contact with a bottom susceptor 220 for conducting heat away from the crucible. Optionally, the heat exchange block 250 may be actively cooled using a water cooling jacket 260. The heat sink preferably has dimensions as large as or larger than the bottom 230 of the crucible 200. For example, a heat exchange block, such as a block of graphite, may be 100 cm by 100 cm by 15 cm, when used with a crucible 200 having a bottom surface that is 84 cm by 84 cm. The crucible 200 and heating elements 240 may be encased in insulation 270. The insulation is equipped with a quartz dip rod 280 that enables monitoring of the progression of the solid-liquid interface both during the melting phase and during unidirectional solidification.

In general, heating at the opening of the crucible and the cooling (either passively by radiating or actively using a cooling water jacket) at the bottom of the crucible are controlled so that the liquid-solid interface progresses in a vector perpendicular from the opening of the crucible toward the bottom surface of the crucible at a rate between about 1 cm/hour and about 4 cm/hour, preferably between about 2 cm/hour and about 3 cm/hour, such as about 2 cm/hour. Melting of the silicon feedstock 110 is closely monitored to track the progress of the molten, liquid silicon toward the monocrystalline silicon seed crystals 120. Preferably, the melt phase of the method of the present invention proceeds until all of the feedstock silicon 110 is completely melted and the monocrystalline silicon seed crystals 120 are partially melted. The progress of the solid-liquid interface may be followed by employing a quartz dip-rod 140, which may be inserted into melt to measure the depth of the melt and determine when the solid-liquid interface has reached the monocrystalline silicon seed crystals 120. In preferred embodiments, the solid/liquid interface is kept flat during its progressing to the seed crystals 120. The interface shape is controlled by adjusting upper heater and side heater power.

Once the silicon melt has been prepared (that is the solid/liquid interface reaching into the seed crystals), the melt may be solidified such as, for example, in a directional solidification process. The direction of the solidification front progresses according to a vector perpendicular from the bottom of the crucible and toward the lid or opening of the crucible. Stated another way, the solid-liquid interface reverses course and proceeds toward the opening of the crucible. The course of the solid-liquid interface is reversed by reducing power to the heating elements located near the opening and optionally the sidewall(s) of the crucible, increasing heat removal via the heat exchanger at the bottom of the crucible, or a combination of the two. In general, the heating at the opening of the crucible and the cooling at the bottom of the crucible are controlled so that the liquid-solid interface progresses in the direction from the bottom surface of the crucible toward the opening of the crucible at a rate between about 0.5 cm/hour and about 3 cm/hour, preferably between about 0.8 cm/hour and about 1.5 cm/hour., such as about 1.2 cm/hour. Again, the progress of the solid-liquid interface may be followed by employing a quartz dip-rod.

In preferred embodiments of the invention, cooling of the melted silicon is controlled so that the solid-liquid interface maintains a convex interface during solidification. By “convex” it is meant that the melt is initially solidified at a faster rate in the center of the crucible than at the crucible sidewalls such that the solid-liquid interface is closer to the crucible opening in the center at the crucible than at the sidewalls of the crucible. It has been discovered that maintaining a slightly convex solid-liquid interface enhances the purity of the cast silicon ingot by driving particles (e.g., Si₃N₄ and SiC) and impurities away from solid/liquid interface to the edge of the crucible and bulk of the melt through natural convection. The convex shape of solid/interface shape is controlled by controlling side heater and upper heater power. For example, increasing side heater power and/or reducing upper heater power will increase interface convexity. To achieve a concave shape, if desired, the upper heating powder should be increased while the side heater power is decreased. The radius of curvature of the convex solid-liquid interface is preferably such that the center of the interface is generally between about 10 mm and about 50 mm higher at the center of the crucible than at the sidewall, preferably between about 15 mm and about 20 mm higher at the center of the crucible than at the sidewall.

The silicon melt typically contains trace impurities such as carbon, nitrogen, and metals. The carbon, nitrogen, and metal (such Fe) impurities have a segregation coefficient less than 1. When the silicon crystal solidifies, these impurities will be ejected into the melt and accumulate in front of growth interface. The impurity concentration can be very high in the narrow layer in front of growth interface, which can increase the incorporation of the impurities in the solid, some even forms precipitates and trapped in the solid. By increasing interface convexity, the natural convection in the melt is increased which can reduce the impurity concentration near the interface and therefore reduce the impurity incorporation into silicon ingot. The impurities are mainly driven to the wall and bulk of melt during growth and eventual all concentrated in the top and edge region.

Upon solidification of essentially the entire silicon ingot but before cooling, the temperature of the ingot surface generally ranges from about 1430° C. to about 1411° C. The ingot may be cooled to room temperature to permit handling and subsequent processing. In preferred embodiments of the invention, the solidified silicon ingot is annealed at a temperature and duration sufficient to reduce thermal stress. The anneal relaxes thermal stresses that may have accumulated during growth and cool down. In general, the silicon ingot may be annealed at a temperature between about 1200° C. and about 1400° C., such as between about 1300° C. and about 1400° C. The duration of the anneal may be between about 1 hour and about 12 hours, such as between about 4 hours and about 8 hours. In one embodiment of the method of the present invention, the silicon ingot is annealed at 1367° C. for 4 hours. In one embodiment of the method of the present invention, the silicon ingot is annealed at 1367° C. for 6 hours. In one embodiment of the method of the present invention, the silicon ingot is annealed at 1300° C. for 5 hours.

Upon completion of the anneal, the cast silicon ingot may be further cooled to ambient temperature, generally at a rate between about 0.5° C./min and about 2° C./min, preferably between about 0.7° C./min and about 1° C./min.

The cooled ingot is then removed from the crucible for further processing. Optionally, the front surface (i.e., the surface that was last to solidify) and the back surface (i.e., the surface that was adjacent the monocrystalline seed crystals) may be cropped. Additionally, the edges of the silicon ingot may be trimmed to remove polycrystalline silicon. Such cropping and trimming yields a cast silicon ingot having substantially uniform purity and crystal orientation throughout the bulk region.

The cast silicon crystalline ingot generally takes the shape of the crucible in which it was solidified, with some variation due to trimming, cropping, or etching as necessary. In general, the ingot comprises two major generally parallel surfaces, one of which is the front surface and the other of which is the back surface. Although herein the front surface is used to describe the surface that was last to solidify and the back surface is used to describe the surface that was adjacent the monocrystalline seed crystals, the use of “front surface” and “back surface” is merely for convenience and is not intended to be limiting. Rather, since the cast silicon ingot is often in the shape of a cube, any surface may be a “front surface” with the opposite face of the cube being the “back surface.” A perimeter surface connects the front surface and the back surface of cast silicon ingot, which may have curvature in embodiments wherein the cast silicon ingot is conical or cylindrical in shape or may comprise four faces in embodiments wherein the cast silicon ingot is cube or cuboidal. A bulk region defines the bulk of the cast silicon ingot between the front surface and the back surface and, e.g., the four faces that make up the perimeter in embodiments wherein the cast silicon ingot is cube or cuboidal. In general, the cast silicon crystalline ingot has no transverse dimension less than about five centimeters, with transverse dimensions of at least about 10 centimeters, or at least about 15 centimeters being preferred. In some embodiments, the cast silicon crystalline ingot has no transverse dimension less than about 25 centimeters. In some embodiments, the ingot dimensions are approximate 84 cm×84 cm×27 cm when grown in a Gen 5 crucible. In some embodiments, the ingot dimensions are 133 cm×133 cm×40 cm when grown in a Gen 8 crucible.

The bulk region of a cast silicon crystalline ingot, in embodiments wherein the silicon melt is intentionally doped with impurities that affect the resistivity of silicon such as boron, gallium, and phosphorus, has a resistivity no greater than about 10 ohm cm, preferably no greater than about 8 ohm cm, even more preferably no greater than about 6 ohm cm, about 4 ohm cm, or even no greater than about 2 ohm cm.

In embodiments of the method of the present invention, the monocrystalline silicon seed crystal(s) are arranged such that no surface of the seed crystals are in contact with the bottom surface of the crucible and preferably the sidewalls of the crucible. Such an arrangement advantageously yields cast silicon ingots having reducing impurities in the bulk of the silicon ingot since the mono-like ingot product is prepared from seed crystals that do not contact the crucible surfaces, which is the source of most impurity. Instead, any impurity that may be present in the solidified ingot is generally present in the non-mono-like ingot perimeter. This ingot perimeter region is generally removed during post-solidification processing. The resulting ingot is thus a mono-like ingot having substantially less impurity at the bottom compared to an ingot prepared by conventional methods having randomly oriented crystal orientation where impurities can diffuse into ingot from crucible bottom. In general, the bulk region of the cast silicon crystalline ingot has an oxygen concentration no greater than about 1×10¹⁸ atoms/cm³, about 8×10¹⁷ atoms/cm³, or about 5×10¹⁷ atoms/cm³. In general, the bulk region of the cast silicon crystalline ingot has an carbon concentration no greater than about 8×10¹⁷ atoms/cm³, about 6×10¹⁷ atoms/cm³, or about 4×10¹⁷ atoms/cm³. In general, the bulk region of the cast silicon crystalline ingot has an nitrogen concentration no greater than about 1×10¹⁶ atoms/cm³, about 8×10¹⁵ atoms/cm³, or about 5×10¹⁵ atoms/cm³. In general, the bulk region of the cast silicon crystalline ingot has an iron concentration no greater than about 1×10¹⁴ atoms/cm³, about 8×10¹³ atoms/cm³, or about 5×10¹³ atoms/cm³.

The cast silicon crystalline ingot is prepared using a monocrystalline silicon seed crystal or multiple monocrystalline silicon seed crystals arranged in identical crystal orientation. Since the crystals are arranged in such a manner, the bulk region of the cast silicon ingot generally has the same crystal orientation as the arranged monocrystalline silicon seed crystals. In some embodiments, all of the monocrystalline silicon seed crystals have crystal orientation (100). In such embodiments, the number of monocrystalline silicon seed crystals may be, e.g., 64, 25, 16, 9, 4, 2 or even one crystal, each (100)-oriented seed crystal resulting in a segment that is substantially monocrystalline. Since all of the crystals have identical crystal orientation, the entirety of the ingot is mono-like in nature. In the mono-like silicon crystal, a monocrystalline segment having (100) orientation comprises at least about 5%, at least about 10%, at least about 25%, at least about 50%, at least about 75%, at least about 98% of the volume of the bulk region of the cast silicon ingot, or even at least 99.9% of the volume of the bulk region of the cast silicon ingot. In some embodiments, the monocrystalline silicon seed crystals have crystal orientation (110), and a monocrystalline segment having (110) orientation comprises at least about 5%, at least about 10%, at least about 25%, at least about 50%, at least about 75%, at least about 98% of the volume of the bulk region of the cast silicon ingot, or even at least 99.9% of the volume of the bulk region of the cast silicon ingot. In some embodiments, the monocrystalline silicon seed crystals have crystal orientation (111), and a monocrystalline segment having (111) orientation comprises at least about 5%, at least about 10%, at least about 25%, at least about 50%, at least about 75%, at least about 98% of the volume of the bulk region of the cast silicon ingot, or even at least 99.9% of the volume of the bulk region of the cast silicon ingot.

Advantageously, the cast silicon crystalline ingot has a dislocation density of less than 1000 dislocations/cm², preferably less than 100 dislocations/cm². A dislocation is a structural defect in crystal lattice, such as an edge dislocation (where a half plane is added or missed) or a screw dislocation (where a lattice is cut open and one half is raised by one lattice vector). Dislocations may originate, for example, from dislocations already in silicon seed crystal, a large non-uniform temperature field during solidification process, or inclusions of foreign particles in the melt, such as Si₃N₄ or SiC particles. Ingots having a dislocation density greater than 1000 dislocations/cm² may yield solar cells with certain negative performance characteristics. For example, high numbers of dislocations may decrease conversion efficiency by as much as 1% percent absolute, increase solar cell reverse current, and decrease solar cell breakdown voltage.

Ingots with low dislocation density may be obtained by applying certain techniques. For example, low dislocation density ingots may be prepared by selecting monocrystalline silicon seed crystals with dislocation density less than 1000 dislocations/cm², preferably less than 100 dislocations/cm². Additionally, the dimensions of the monocrystalline silicon seed crystals are preferably substantially the same as the final solar cell produced from the cast silicon ingot. Preferably, the crystal orientations of the mating surface of monocrystalline silicon seed crystals are identical, such as (100) to (100) or (110) to (110). Additionally, during the melt, a low gradient temperature field is preferably maintained during the entire process from heating, melting, solidification, annealing, and cool down. The convex solid-liquid interface is effective to inhibit the generation of Si₃N₄ and SiC particle generation, and the convex interface effectively drives such impurities, which may cause dislocations, to the edges of the solidifying crystal ingot. Other techniques for minimizing the generation of such particles include covering the crucible opening, with e.g., a SiC coated lid and creating a laminar flow on the melt surface using inert gas, such as argon.

Wafers cut from the cast silicon ingots grown according to the method of the present invention have demonstrated solar cell efficiency of at least 15%, at least about 17.5%, and preferably at least 18.7%, such as at least 19% due to lower dislocation density and higher purity. Advantageously, the wafers achieve high solar cell efficiency with substantially reduced light induced degradation. Generally, the light induced degradation is less than 0.5%, preferably less than 0.2%, even more preferably less than 0.1%, or even less than 0.05%. Additionally, wafers cut from cast silicon ingots and formed into solar cells demonstrated open circuit voltages of at least about 0.600 V, preferably at least about 0.620 V, such as at least about 0.630 V, even as much as at least about 0.635 V.

The cast silicon ingot may then be cut into one or more pieces depending upon the intended use of the mono-like crystalline silicon product. For example, the ingot may be sliced to match the dimensions of a desired solar cell. In some embodiments, the cast silicon ingot may be sliced and cut into silicon parts for use in the interior chamber of wafer etch tools. Wafers may be prepared by slicing these pieces by, for example, use of a wiresaw to produce sliced wafers or silicon parts, which may then be cleaned, lapped and etched according to conventional processes.

By seeding the crucible with multiple monocrystalline silicon seed crystals prior to forming the melt and ensuring that each seed crystal is arranged to have identical orientations, the multicrystalline cast silicon ingot produced by directional solidification is an agglomeration of crystal grains with identical crystal orientations of the grains relative to each other. Additionally, since the monocrystalline silicon seed crystals are arranged such that no surface of the seed crystals contacts the bottom of the crucible and preferably no surface of the seed crystals contacts the sidewall of the crucible, sporadic nucleation of seeds is avoided, thereby avoiding the formation of randomly oriented crystal grains in the final cast silicon ingot.

Having described the invention in detail, it will be apparent that modifications and variations are possible without departing from the scope of the invention defined in the appended claims.

### Examples

The following non-limiting examples are provided to further illustrate the present invention.

### Example 1

### Granular Polycrystalline Silicon Spacer and Wafer Seed Crystals

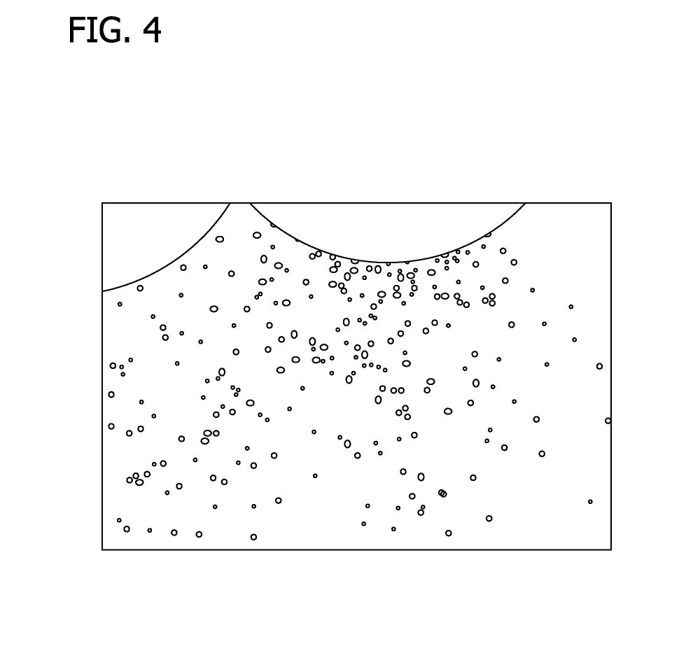

Granular polycrystalline silicon was charged into a quartz crucible having interior dimensions of 84 cm×84 cm×40 cm. The interior surface of the crucible was coated with Si₃N₄. The granular polysilicon had a purity of >6N and sizes range from 1 mm to 3 mm in diameter, with most granules having a diameter of about 2 mm. About 3 kg of the granular polycrystalline silicon was charged to the crucible, which was sufficient to provide coverage of 2% of the bottom interior surface of the crucible. The granular polycrystalline silicon spacer enabled arrangement of tiles of monocrystalline silicon seed crystals having dimensions 3 to 5 mm thickness and 300 mm diameter. The seed crystals were cut from a 300 mm Czochralski-grown mono crystal rod. See FIG. 4, which is a depiction of a bottom surface of a crucible to which granular polycrystalline silicon has been charged with monocrystalline silicon wafers arranged thereon.

### Example 2

### Silicon Strip Spacer and Single Layer of Monocrystalline Silicon Seed Crystals

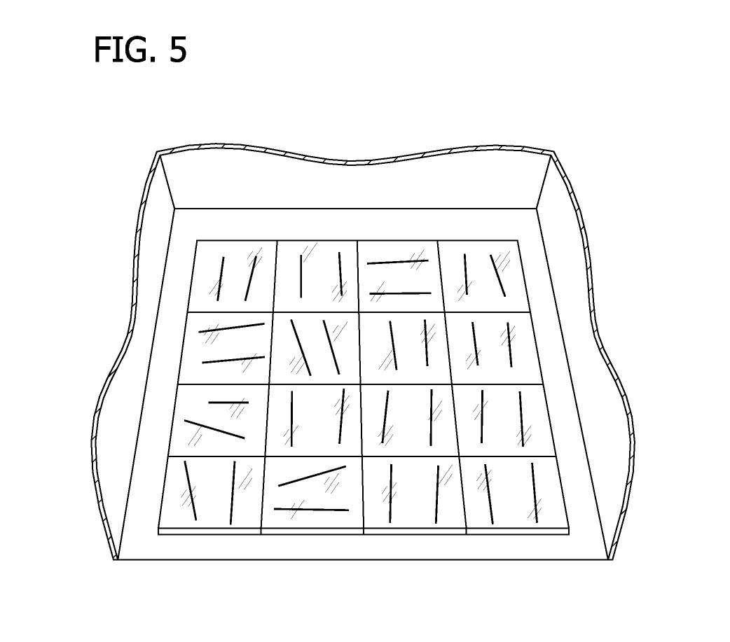

32 polycrystalline silicon strips were arranged on the bottom surface of a quartz crucible having interior dimensions of 84 cm×84 cm×40 cm. The interior surface of the crucible was coated with Si₃N₄. The silicon strips were 750 micrometers thick, between 150 millimeters and 300 millimeters long, and between 10 millimeters and 20 millimeters wide. The silicon strips were cut from 200-300 mm Si wafers. 16 tiles of monocrystalline silicon seed crystals that were 158 mm by 158 mm and a thickness of between 30 millimeters and 50 millimeters were arranged on the polycrystalline strips such that no surface of the seed crystals were in contact with the bottom or sidewalls of the crucible. The seeds were oriented in (100) for all surfaces and were cut from 300 mm CZ monocrystalline rods using a band saw. See FIG. 5, which is a depiction of an arrangement of a layer of monocrystalline silicon seed crystals on silicon strips.

### Example 3

### Silicon Strip Spacer and Sacrificial Monocrystalline Silicon Seed Crystal Stacks

Silicon strips were arranged on the bottom surface of a quartz crucible having interior dimensions of 84 cm×84 cm×40 cm. A larger crucible having dimensions of 133 cm×133 cm×60 cm was also prepared in the same manner as described in this example. The interior surface of the crucible was coated with Si₃N₄. The silicon strips were 750 micrometers thick, between 150 millimeters and 300 millimeters long, and between 10 millimeters and 20 millimeters wide. The silicon strips were cut from 200-300 mm Si wafers.

Tiles of sacrificial seed crystals that were 156 mm by 20 to 60 mm and having a thickness between 30 and 50 millimeters were arranged on the polycrystalline strips such that no surface of the sacrificial seed crystals were in contact with the bottom or sidewalls of the crucible. The sacrificial seeds oriented in (100) for all surfaces were cut from 300 mm CZ mono crystal rods using band saw.

The monocrystalline silicon seed crystals that were 156 mm by 156 mm and a thickness between 30 and 50 mm were arranged on the silicon strips such that no surface of the monocrystalline silicon seed crystals were in contact with the bottom of the crucible. The seeds oriented in (100) for all surfaces were cut from 300 mm CZ mono crystal rods using band saw. Sacrificial seed crystals having rectangular shape and dimensions of 156 mm×20 to 60 mm×30 to 50 mm were arranged around the periphery of the monocrystalline silicon seed crystals, thereby forming a buffer of sacrificial seed crystals between the monocrystalline silicon seed crystals and the sidewalls of the crucible.

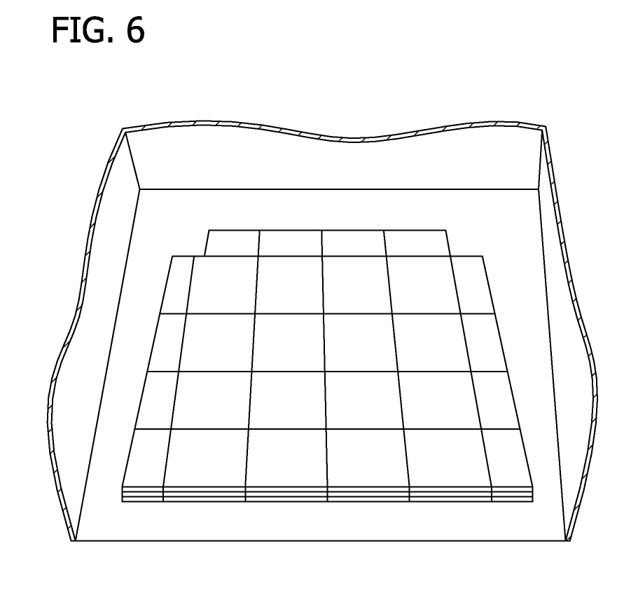

See FIG. 6, which is a depiction of an arrangement of a layer of monocrystalline silicon crystals, wherein a layer of monocrystalline silicon seed crystals are separated from crucible bottom and walls by a grid of silicon strips underneath and a border of sacrificial seed crystals around the periphery of the monocrystalline silicon seed crystals.

### Example 4

### Preparation of a Silicon Melt

The crucible prepared according to the method described in Example 3 with a layer of monocrystalline silicon seed crystals was charged with 400 kg of granular and chunk_polycrystalline silicon. Chunk Si was placed in the middle of crucible and granular Si was placed around the chunk Si and against the crucible wall to protect the coating and crucible during heatup.

Power was applied to the ramp side heater and upper heater to achieve a temperature of 1490° C. at the crucible opening. The side heater temperature was kept at 1515° C. The axial temperature gradient was about 5° C./cm. The melt down rate was about 2 cm/hour and was reduced to about 1 cm/hour when the interface was close to the seed crystal surface. The temperature was held below 1414° C. near the monocrystalline seed crystals by keeping the heat exchanger temperature below 1300° C. The cooling heat exchanger maintained the temperature below the melting point of silicon at the seed crystals by a combination of radiation and conduction which can be done by opening bottom insulation and lifting side insulation. The heat was maintained or increased to the molten charge so that the liquid-solid interface advanced toward the seed(s) (i.e., a vector perpendicular from the opening and toward the bottom of the crucible) while the location of the solid-liquid interface was monitored periodically using a quartz stick, such as one measurement every two hours before the liquid-solid interface was about 2 cm away from seed surface, one measurement every hour when interface was within 2 cm to the seed surface. When interface reached the seed surface or about 1 cm below seed surface, the melt was completed.

### Example 5

### Preparation of a Silicon Melt

A crucible having dimensions 133 cm×133 cm×60 cm prepared according to the method described in Example 3 with sacrificial monocrystalline silicon seed crystals was charged with 1650 kg of granular and chunk polycrystalline silicon. Chunk Si was placed in the middle of crucible and granular Si was placed around the chunk Si and against the crucible wall to protect coating and crucible during heatup.

Power was applied to the ramp side heater and upper heater to achieve a temperature of 1525° C. at the crucible opening. The ambient atmosphere during meltdown was Argon at a pressure ranging from 500 to 900 millibar. The side heater temperature was kept at 1500° C. The axial temperature gradient was about 4° C./cm. The melt down rate was about 1.5 cm/hour and was reduced to 1 cm/hour when the solid/liquid interface was close to the seed crystal surface. The temperature was held below 1414° C. near the monocrystalline seed crystals by using cooling heat exchanger. The cooling heat exchanger maintained the temperature below the melting point of silicon at the seed crystals by a combination of radiation and conduction. The heat was maintained or increased to the molten charge so that liquid and solid interface advanced toward the seed(s) (i.e., a vector perpendicular from the opening and toward the bottom of the crucible) while the location of the solid-liquid interface was monitored periodically using a quartz stick, such as one measurement every two hours before interface was about 2 cm away from seed surface, one measurement every hour when interface was within 2 cm to the seed surface. When interface reached the seed surface or about 1 cm below seed surface, the melt was completed.

### Example 6

### Preparation of a Cast Multicrystalline Silicon Ingot

When the solid-liquid interface of a silicon melt prepared according to either of Example 4 or 5 reached a surface of the monocrystalline silicon seed crystals, the heating power was reduced and the cooling rate was increased, which slowed and eventually stopped the progression of the solid-liquid interface. The heating/cooling profile allowed the monocrystalline silicon seed crystals to partially melt.

Thereafter, additional heat was withdrawn from the bottom of the crucible to reverse the direction of the progression of the solid-liquid interface, which began growth of the multicrystalline silicon ingot. The heat applied to the crucible may be decreased by adjusting the radiation view angle or the distance between heat exchanger and cooling jacket, or a combination of the two, as necessary. Heat was removed constantly, which caused the solid-liquid interface to progress perpendicularly from the bottom of the crucible toward the opening. The shape of the solid-liquid interface was maintained convex by providing higher power to side heater compared to the upper heater.

The ingot was bricked along the joint of seeds so that each brick was grown from one single seed tile. The C/O was evaluated by FTIR for each ingot and was less than 10 ppma. The Si₃N₄ impurity content, SiC inclusions, lifetime, and resistivity of each brick were inspected by a commercial solar brick inspection tool. The metal concentration was evaluated by MASS spectroscopy. The dislocation density was evaluated by PL and etch pit counting.

### Example 7

### High Temperature Anneal

Upon solidification of the multicrystalline cast silicon ingot prepared according to the method of any of Example 6, the ingot was annealed inside the furnace to reduce thermal stress by maintaining the grown crystal in a relatively isothermal environment. Annealing occurred at 1367° C. for 6 hours. In another experiment, annealing occurred at 1300° C. for 5 hours.

### Example 8

### Mono-like Crystalline Silicon Ingot

A mono-like crystalline silicon ingot was prepared by casting. Four large seed crystals having (110) crystal orientation were arranged on a grid of Si strips which placed on the crucible bottom. The strips had dimension of 300 mm long×20 mm wide×750 micrometers thick and arranged according to the dimension of seeds. The dimensions of each seed crystal were 280 to 300 mm×280 to 370 mm×40 to 50 mm. The crucible is standard Si₃N₄ coated quartz crucible with dimension of 84 cm×84 cm×40 cm. Granular and chunk polycrystalline (410 kg) was charged on top of the seed crystals. The charged was heated to 1495° C. at the top of the charge. The bottom of the crucible was kept below 1310° C. The polycrystalline silicon charged was melted until the solid-liquid interface front melted a portion of the seed surface. The progress of the interface as monitored using a quartz dipstick. Upon reaching the seed surface, the melt was solidified unidirectionally from the partially melted seeds by extracting heat from the bottom of the crucible and reducing the power into the charge until the ingot was fully solidified.

The ingot was annealed at a temperature of 1367° C. for 4-6 hours. The ingot was then cooled to <200° C. and unloaded from the crucible. The edge of the ingot was trimmed to remove polycrystalline silicon, and the top and bottom part of the ingot were cropped. A large (110) oriented, mono-like crystal silicon ingot was made comprising four distinct (110) oriented crystal segments. The regions at the joints of seeds typically have high density of dislocations.

The resistivity, oxygen concentration, carbon concentration, nitrogen concentration, and iron concentration of the (110) oriented, mono-like crystal silicon ingot was determined at the bottom, middle, and top of the ingot. The following table provides the quantitative results.

| | Re- | | | | |
|---|---|---|---|---|---|
| | sis- | | | | |
| | tiv- | | | | |
| | ity | | | | |
| | (ohm | [oxygen] | [carbon] | [nitrogen] | [iron] |
| Position | cm) | (atoms/cm³) | (atoms/cm³) | (atoms/cm³) | (atoms/cm³) |
| Bottom | 1.472 | 1.65 × 10¹⁷ | 3.39 × 10¹⁶ | 2.44 × 10¹⁵ | 2.77 × 10¹³ |
| Middle | 1.270 | 1.32 × 10¹⁷ | 4.60 × 10¹⁶ | 2.28 × 10¹⁵ | 3.61 × 10¹³ |
| Top | 1.086 | 8.47 × 10¹⁶ | 1.41 × 10¹⁷ | 2.02 × 10¹⁵ | 3.54 × 10¹³ |

### Example 9

### Solar Cell Electrical Data of Wafers Sliced from a Mono-Like Crystalline Silicon Ingot

Multiple wafers were sliced from a mono-like crystalline silicon ingot prepared according to the method of described in Example 8. The wafers had dimensions of 156 mm×156 mm×200 um. The wafers had surface crystalline orientation of (100). The wafers were tested for solar conversion efficiency using industry screen print technology. The process involved KOH-texturing by etching the wafers in an aqueous KOH solution. Next, phosphorus diffusion occurs by POCl₃ in-diffusion. Thereafter, the wafers were subjected to edge-isolation. The wafers were then coated with silicon-nitride to coat with an anti-reflective coating. Finally, the wafers were screen printed on the front and coated with Al on the back side field, co-firing contacted (annealed to ensure proper contact formation), and subjected to I-V measurement/sorting. Fifteen wafers were tested and exhibited the open circuit voltages and solar cell efficiencies as shown in the following table. Additionally, the light induced degradation was no greater than 0.1% for any cell tested.

| Wafer Number | Open Circuit Voltage (V) | Solar Cell Efficiency (%) |
|---|---|---|
| 1 | 0.635 | 19.00 |
| 2 | 0.636 | 18.99 |
| 3 | 0.636 | 18.97 |
| 4 | 0.637 | 18.94 |
| 5 | 0.637 | 18.94 |
| 6 | 0.636 | 18.94 |
| 7 | 0.636 | 18.94 |
| 8 | 0.636 | 18.93 |
| 9 | 0.636 | 18.93 |
| 10 | 0.636 | 18.91 |
| 11 | 0.635 | 18.90 |
| 12 | 0.637 | 18.90 |
| 13 | 0.635 | 18.90 |
| 14 | 0.636 | 18.90 |
| 15 | 0.637 | 18.90 |

In view of the above, it will be seen that the several objects of the invention are achieved. As various changes could be made in the above-described process without departing from the scope of the invention, it is intended that all matters contained in the above description be interpreted as illustrative and not in a limiting sense. In addition, when introducing elements of the present invention or the preferred embodiment(s) thereof, the articles “a,” “an,” “the” and “said” are intended to mean that there are one or more of the elements. The terms “comprising,” “including” and “having” are intended to be inclusive and mean that there may be additional elements other than the listed elements.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A method of preparing a silicon melt in a crucible for use in the manufacture of cast silicon, wherein the crucible comprises an opening, an opposing bottom surface, and at least one sidewall joining the opening and the bottom surface, the method comprising:
charging a silicon spacer to the bottom surface of the crucible;
arranging a monocrystalline silicon seed crystal on the silicon spacer such that no surface of the monocrystalline silicon material is in contact with the bottom surface of the crucible;
charging polycrystalline silicon feedstock to the crucible; and
applying heat through at least one of the opening and the at least one sidewall in order to form a partially melted charge of silicon in the crucible.

2. The method of claim 1 wherein the crucible comprises four sidewalls and has a cuboid shape and wherein the depths of the sidewalls as measured from the opening of the crucible to the bottom surface of the crucible are between about 25 cm and about 70 cm and the lengths of the sidewalls as measured from the points at which the sidewalls intersect is between about 50 cm and about 140 cm.

3. The method of claim 1 wherein the monocrystalline silicon seed crystal is arranged such that no surface of the monocrystalline silicon seed crystal is in contact with the at least one sidewall of the crucible.

4. The method of claim 1 wherein the polycrystalline silicon spacer comprises granular polycrystalline.

5. The method of claim 1 wherein the silicon spacer comprises strips of silicon.

6. The method of claim 5 wherein the strips have thickness of between 250 micrometers and 1250 micrometers, wherein the thickness is measured from a point of contact between the spacer material and the bottom surface and a point of contact between the spacer and the monocrystalline silicon seed crystal.

7. The method of claim 1 wherein the monocrystalline silicon seed crystal comprises two major, generally parallel surfaces, one of which is a front surface and the other of which is a back surface.

8. The method of claim 7 wherein monocrystalline silicon seed crystal is tile-shaped and each length of the two major generally parallel surfaces range from about 50 mm to about 450 mm.

9. The method of claim 8 wherein the thickness of the tile-shaped crystal ranges from about 10 mm to about 50 mm, wherein the thickness is measured from the lowest point on the front surface to the transverse point on the back surface.

10. The method of claim 1 wherein sacrificial monocrystalline silicon seed crystals are arranged on peripheral of the monocrystalline silicon seed crystals and further wherein the sacrificial monocrystalline silicon seed crystals are arranged such that no surface of the sacrificial monocrystalline silicon seed crystals are in contact with the bottom and the at least one sidewall of the crucible.

11. The method of claim 10 wherein each of the monocrystalline silicon seed crystals have the same crystal orientation.

12. The method of claim 1 wherein between about 270 kg and about 1650 kg of the polycrystalline silicon feedstock is charged to the crucible.

13. The method of claim 1 wherein the polycrystalline silicon feedstock comprises granular polycrystalline silicon, chunk polycrystalline silicon, or a combination of granular polycrystalline silicon and chunk polycrystalline silicon.

14. The method of claim 1 wherein a heat source is located near the opening of the crucible and the heat is applied to melt the polycrystalline silicon feedstock such that a liquid-solid interface progresses in a direction generally perpendicular to the opening of the crucible and toward the bottom surface of the crucible.

15. The method of claim 14 wherein the liquid-solid interface maintains a flat shape as the interface progresses toward the surface of seed crystals.

16. The method of claim 14 further comprising a step selected from the group consisting of reducing the heat applied to the opening of the crucible, cooling the bottom of the crucible, and a combination thereof;
wherein this step occurs after the liquid-solid interface contacts the monocrystalline silicon seed crystal.

17. A method of manufacturing cast silicon, the method comprising:
charging a silicon spacer to a crucible, wherein the crucible comprises an opening, an opposing bottom surface, and at least one sidewall joining the opening and the bottom surface;
arranging a monocrystalline silicon seed crystal on the silicon spacer such that no surface of the monocrystalline silicon seed crystal is in contact with the bottom surface of the crucible;
charging polycrystalline silicon feedstock to the crucible;
applying heat through at least one of the opening and the sidewall in order to form a partially melted charge of silicon in the crucible, wherein the heat is applied to melt the polycrystalline silicon feedstock such that a liquid-solid interface progresses in a direction generally perpendicular from the opening of the crucible and toward the bottom surface of the crucible and the liquid-solid interface is maintained flat when progresses toward the surface of seed crystals;
reducing the heat applied to the opening of the crucible and/or cooling the bottom of the crucible after the liquid-solid interface contacts the monocrystalline silicon seed crystal, thereby causing the liquid-solid interface to reverse direction and progress in a direction generally perpendicular from the bottom surface of the crucible and toward the opening of the crucible,
wherein at least a portion of the monocrystalline silicon seed crystal remains solid throughout the entire method.

18. The method of claim 17 wherein the crucible comprises four sidewalls and has a cuboid shape and wherein the depths of the sidewalls as measured from the opening of the crucible to the bottom surface of the crucible are between about 25 cm and about 70 cm and the lengths of the sidewalls as measured from the points at which the sidewalls intersect is between about 50 cm and about 140 cm.

19. The method of claim 17 wherein between about 270 kg and about 1650 kg of the polycrystalline silicon feedstock is charged to the crucible.

20. The method of claim 17 wherein the liquid-solid interface progresses in the direction from the opening of the crucible toward the bottom surface of the crucible at a rate between about 0.5 cm/hour and about 3 cm/hour.

21. The method of claim 17 wherein the liquid-solid interface progresses in the direction from the bottom surface of the crucible toward the opening of the crucible at a rate between about 0.5 cm/hour and about 3 cm/hour.

22. The method of claim 21 wherein the liquid-solid interface maintains a convex shape as the interface progresses from the bottom surface of the crucible toward the opening.

23. The method of claim 17 further comprising annealing the cast silicon at a temperature and duration sufficient to reduce thermal stress.

24. The method of claim 23 wherein the cast silicon is cooled at a rate between about 0.5° C./min and about 2° C./min.

25. The method of claim 1 wherein the crucible comprises four sidewalls and has a cuboid shape and wherein the depths of the sidewalls as measured from the opening of the crucible to the bottom surface of the crucible are between about 25 cm and about 70 cm and the lengths of the sidewalls as measured from the points at which the sidewalls intersect is at least 130 cm.

26. The method of claim 1 further comprising reducing the heat applied to the opening of the crucible and/or cooling the bottom of the crucible after the liquid-solid interface contacts the monocrystalline silicon seed crystal, thereby causing the liquid-solid interface to reverse direction and progress in a direction generally perpendicular from the bottom surface of the crucible and toward the opening of the crucible,
wherein the liquid-solid interface maintains a convex shape as the liquid-solid interface progresses from the bottom surface of the crucible toward the opening and further wherein at least a portion of the monocrystalline silicon seed crystal remains solid throughout the entire method.

27. The method of claim 26 wherein the radius of curvature of the convex solid-liquid interface is such that the center of the interface is between about 10 mm and about 50 mm higher at the center of the crucible than at the sidewall.

28. The method of claim 26 wherein the radius of curvature of the convex solid-liquid interface is such that the center of the interface is between about 15 mm and about 20 mm higher at the center of the crucible than at the sidewall.

29. The method of claim 5 wherein the strips have thickness of between 750 micrometers and 1250 micrometers, wherein the thickness is measured from a point of contact between the spacer material and the bottom surface and a point of contact between the spacer and the monocrystalline silicon seed crystal.
